(19) United States
(12) Patent Application Publication
(10) Pub. No.: US 2026/0292982 A1
(43) Pub. Date: Sep. 24, 2026

(54) WIRING BOARD AND PROBE CARD

(71) Applicant: KYOCERA Corporation, Kyoto-shi, Kyoto (JP)

(72) Inventor: Jun SETOGUCHI, Kirishima-shi, Kagoshima (JP)

(73) Assignee: KYOCERA Corporation, Kyoto-shi, Kyoto (JP)

(21) Appl. No.: 19/143,023

(22) PCT Filed: Dec. 26, 2023
(86) PCT No.: PCT/JP2023/046548

§ 371 Date: Jun. 25, 2025

(30) Foreign Application Priority Data
Dec. 28, 2022 (JP) 2022-211021

(51) Int. Cl. H05K 1/11; G01R 1/073

(52) U.S. Cl. CPC H05K 1/115; G01R 1/07342

(57) ABSTRACT

An insulating substrate includes a center region closer to a center and an outer peripheral region closer to an outer periphery in transparent plan view. Among second via conductors located in the outer peripheral region, a number of second via conductors with a portion located within half a thickness of the insulating substrate from a first surface is larger than a number of second via conductors not located within half the thickness of the insulating substrate from the first surface.

### TECHNICAL FIELD

The present disclosure relates to a wiring board and a probe card.

### BACKGROUND

Japanese Unexamined Patent Application Publication No. 2011-009694 describes a wiring board for a probe card. The wiring board includes multiple wiring conductors extending from one surface of the board toward the other surface of the board.

### SUMMARY

According to the present disclosure, a wiring board includes an insulating substrate, multiple first electrodes, multiple second electrodes, and multiple wiring conductors. The insulating substrate includes a first surface, a second surface located opposite to the first surface, and multiple wiring layers. The multiple first electrodes are located on the first surface. The multiple second electrodes are located on the second surface. The multiple wiring conductors extend between respective ones of the multiple first electrodes and corresponding ones of the multiple second electrodes. The multiple wiring conductors include respective ones of film conductors, respective ones of first via conductors, and respective ones of second via conductors. The film conductors are each located at any of the multiple wiring layers. The first via conductors extend between the respective ones of the film conductors and corresponding ones of the multiple first electrodes. The second via conductors extend between the respective ones of the film conductors and corresponding ones of the multiple second electrodes. The insulating substrate includes a center region and an outer peripheral region. When a line segment connecting a center and an outer periphery of the insulating substrate in transparent plan view is drawn, the center region covers a range of two-thirds of the line segment closer to the center in any direction, and the outer peripheral region covers a range of one-thirds of the line segment closer to the outer periphery in any direction. The multiple first electrodes are located in the center region. At least some of the multiple second electrodes are located in the outer peripheral region. Among the second via conductors located in the outer peripheral region, a number of the second via conductors with a portion located within half a thickness of the insulating substrate from the first surface is larger than a number of the second via conductors not located within half the thickness of the insulating substrate from the first surface.

According to the present disclosure, a probe card includes the wiring board and multiple probe pins.

### BRIEF DESCRIPTION OF THE DRAWINGS

FIG. 1A is a plan view of a wiring board according to Embodiment 1 of the present disclosure.

FIG. 1B is a back view of the wiring board according to Embodiment 1 of the present disclosure.

FIG. 2 is a vertical sectional view of the wiring board of Embodiment 1.

FIG. 3A is a diagram for explaining a center region and an outer peripheral region of the wiring board in Embodiment 1.

FIG. 3B is a diagram for explaining a center region and an outer peripheral region of a wiring board in Variation 1.

FIG. 3C is a diagram for explaining a center region and an outer peripheral region of a wiring board in Variation 2.

FIG. 4A is a view of a wiring pattern of Embodiment 1, where a first surface is illustrated.

FIG. 4B is a view of the wiring pattern of Embodiment 1, where a third wiring layer is illustrated.

FIG. 4C is a view of the wiring pattern of Embodiment 1, where a fifth wiring layer is illustrated.

FIG. 4D is a view of the wiring pattern of Embodiment 1, where a seventh wiring layer is illustrated.

FIG. 5A is a view of the wiring pattern of Embodiment 1, where a ninth wiring layer is illustrated.

FIG. 5B is a view of the wiring pattern of Embodiment 1, where an eleventh wiring layer is illustrated.

FIG. 5C is a view of the wiring pattern of Embodiment 1, where a second surface is illustrated.

FIG. 6 is a vertical sectional view of a wiring board of Embodiment 2.

FIG. 7A is a view of a wiring pattern of Embodiment 2, where a first surface is illustrated.

FIG. 7B is a view of the wiring pattern of Embodiment 2, where a third wiring layer is illustrated.

FIG. 7C is a view of the wiring pattern of Embodiment 2, where a fourth wiring layer is illustrated.

FIG. 7D is a view of the wiring pattern of Embodiment 2, where a sixth wiring layer is illustrated.

FIG. 8A is a view of the wiring pattern of Embodiment 2, where a ninth wiring layer is illustrated.

FIG. 8B is a view of the wiring pattern of Embodiment 2, where an eleventh wiring layer is illustrated.

FIG. 8C is a view of the wiring pattern of Embodiment 2, where a thirteenth wiring layer is illustrated.

FIG. 8D is a view of the wiring pattern of Embodiment 2, where a second surface is illustrated.

FIG. 9A is a view of a wiring pattern of a wiring board of Embodiment 3, where a first surface is illustrated.

FIG. 9B is a view of the wiring pattern of the wiring board of Embodiment 3, where a third wiring layer is illustrated.

FIG. 10A is a view of the wiring pattern of the wiring board of Embodiment 3, where a fifth wiring layer is illustrated.

FIG. 10B is a view of the wiring pattern of the wiring board of Embodiment 3, where a seventh wiring layer is illustrated.

FIG. 11A is a view of the wiring pattern of the wiring board of Embodiment 3, where a ninth wiring layer is illustrated.

FIG. 11B is a view of the wiring pattern of the wiring board of Embodiment 3, where an eleventh wiring layer is illustrated.

FIG. 12 is a view of the wiring pattern of the wiring board of Embodiment 3, where a second surface is illustrated.

FIG. 13A is a view of a probe card according to an embodiment of the present disclosure.

FIG. 13B is a view of a probe card according to a variation.

### DETAILED DESCRIPTION

Hereinafter, each embodiment of the present disclosure is described in detail with reference to the drawings.

### Embodiment 1

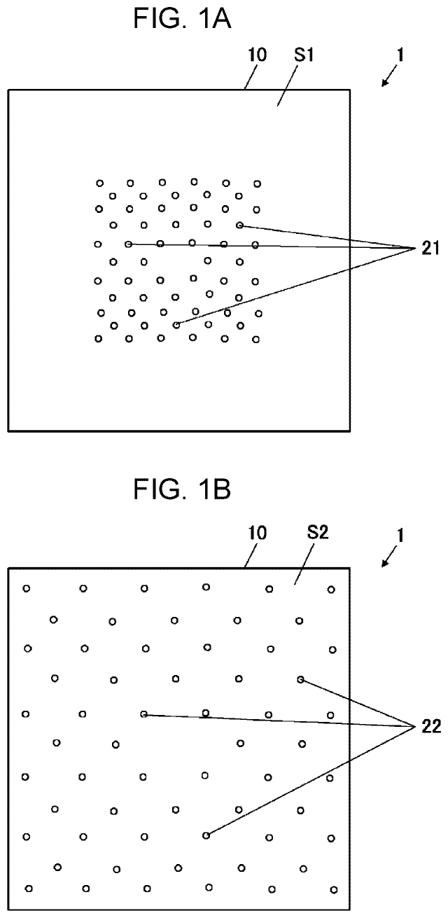

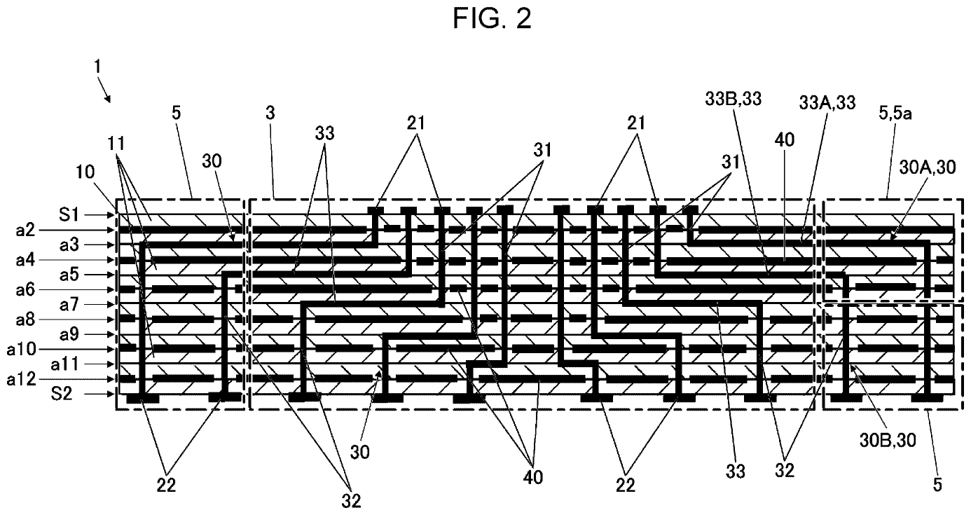

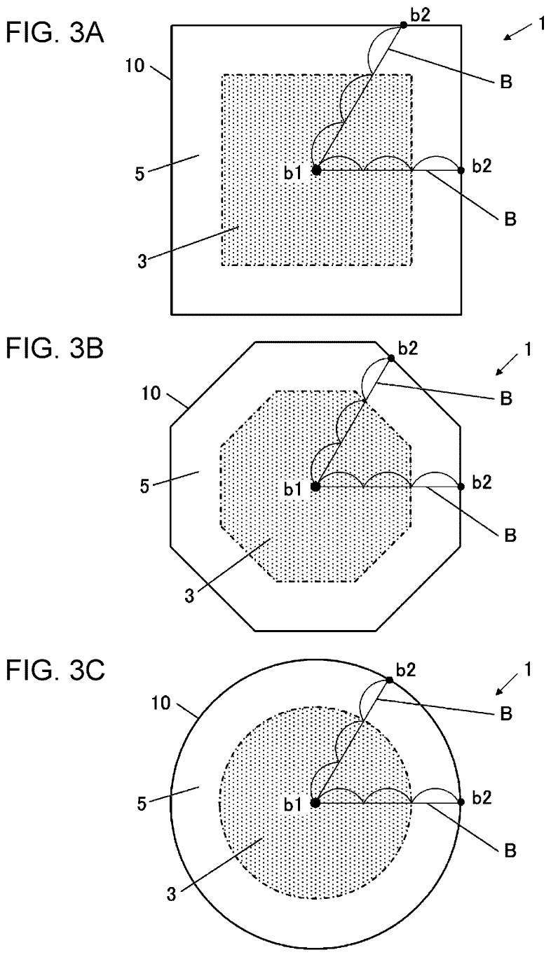

FIGS. 1A and 1B are a plan view and a back view, respectively, of a wiring board according to Embodiment 1 of the present disclosure. FIG. 2 is a vertical sectional view of the wiring board according to Embodiment 1. In the drawings, with regard to the same components including a large number thereof, reference characters are given to only some of the components. The same and/or similar holds for FIG. 3 and thereafter.

According to Embodiment 1 of the present disclosure, a wiring board 1 is a wiring board for a probe card. A probe card is a card incorporated in a device to test an electronic circuit (specifically, a plurality of semiconductor circuits on a semiconductor wafer). More specifically, the probe card is interposed between a signal processing circuit and an electronic circuit of a test target object and is coupled to the electronic circuit of the test target object with multiple probe pins interposed therebetween. The signal processing circuit inputs and outputs a signal or voltage for testing.

The wiring board 1 includes an insulating substrate 10, multiple first electrodes 21, multiple second electrodes 22, multiple wiring conductors 30, and a ground conductor 40. The insulating substrate 10 includes a first surface S1, a second surface S2, and multiple wiring layers a2 to a12. The multiple first electrodes 21 are located on the first surface S1. The multiple second electrodes 22 are located on the second surface S2. The multiple wiring conductors 30 extend between respective ones of the multiple first electrodes and corresponding ones of the multiple second electrodes.

The multiple wiring layers a2 to a12 may be layers extending approximately parallel to the first surface S1 and the second surface S2. The insulating substrate 10 includes multiple insulating layers 11 stuck on one another. One surface of each insulating layer 11 may form, that is, two insulating layers 11 vertically overlapping one another may form therebetween one wiring layer. The insulating substrate 10 may include ceramic.

One wiring conductor 30 includes a film conductor 33 located at any of the multiple wiring layer a2 to a12, a first via conductor 31 extending between the film conductor 33 and the first electrode 21, and a second via conductor 32 extending between the film conductor 33 and the second electrode 22. The film conductor 33 is located along one wiring layer and is a layer-shaped and band-shaped conductor. The film conductor 33 has a shape elongated along a wiring route. The wiring route may have a linear shape or a curved shape, or may include one or more curves in the wiring route. The first via conductor 31 extends between the first surface S1 and the wiring layer where the film conductor 33 is located, and may penetrate one or more insulating layers 11 located between the first surface S1 and the wiring layer where the film conductor 33 is located. The first via conductor 31 may extend in a direction intersecting with (for example, a direction orthogonal to) the first surface S1. The second via conductor 32 extends between the second surface S2 and the wiring layer where the film conductor 33 is located, and may penetrate one or more insulating layers 11 located between the second surface S2 and the wiring layer where the film conductor 33 is located. The second via conductor 32 may extend in a direction intersecting with (for example, a direction orthogonal to) the second surface S2. The first via conductor 31 may be coupled to one end of the film conductor 33, and the second via conductor 32 may be coupled to another end of the film conductor 33.

The ground conductor 40 may be provided, in such a manner as to extend in two directions along the wiring layer while avoiding the first via conductor 31 and the second via conductor 32, to each of the wiring layers a2, a4, a6, a8, a10, and a12 where the film conductor 33 is not located. The ground conductor 40 may be a solid conductor extending planarly.

A structure of the multiple wiring conductors 30 is described with the wiring board 1 divided into two regions of a center region 3 and an outer peripheral region 5.

FIGS. 3A to FIG. 3C are diagrams for explaining the center region and the outer peripheral region of the wiring board. FIG. 3A is an explanatory diagram of Embodiment 1, FIG. 3B is an explanatory diagram of Variation 1, and FIG. 3C is an explanatory diagram of Variation 2.

As illustrated in FIG. 3A, the center region 3 is a region at a center when the wiring board 1 is seen in transparent plan view. The outer peripheral region 5 is a region of an outer peripheral portion when the wiring board 1 is seen in transparent plan view, and is a region except for the center region 3. More specifically, when a line segment B connecting a center point b1 and an arbitrary outer peripheral point b2 of the wiring board 1 in transparent plan view is drawn, the center region 3 is a region covering a range of two-thirds of the line segment B closer to the center in any direction. The center point b1 corresponds to a center of gravity of a two-dimensional figure corresponding to a shape of the wiring board 1 in transparent plan view. The outer peripheral region 5 is a region covering a range of one-thirds of the line segment B closer to an outer periphery in any direction. The center region 3 may correspond to a region overlapping a terminal of an electronic circuit of a test target object in a vertical direction. The transparent plan view means transparent view in a direction orthogonal to the first surface S1. The vertical direction means the direction orthogonal to the first surface S1.

As illustrated in FIGS. 3B and 3C, when the wiring board 1 has a different two-dimensional shape, each of the center region 3 and the outer peripheral region 5 also has a different shape corresponding to the two-dimensional shape of the wiring board 1.

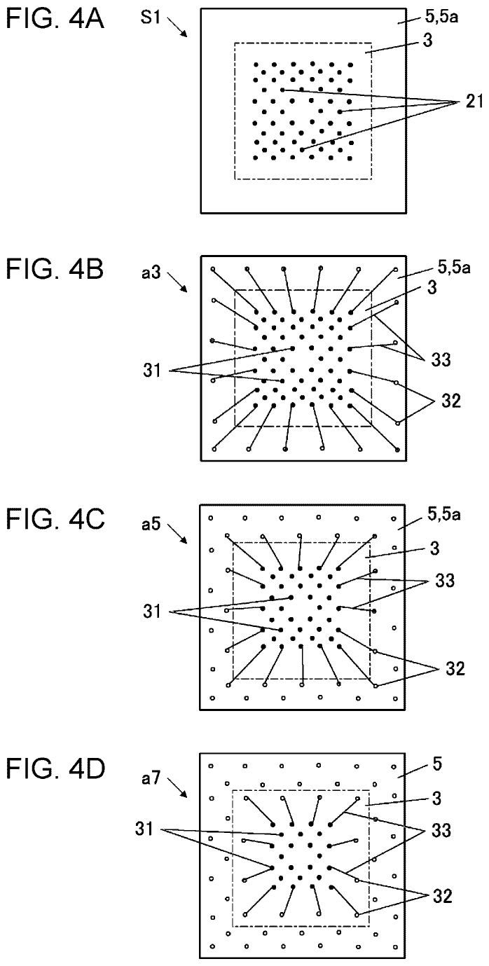

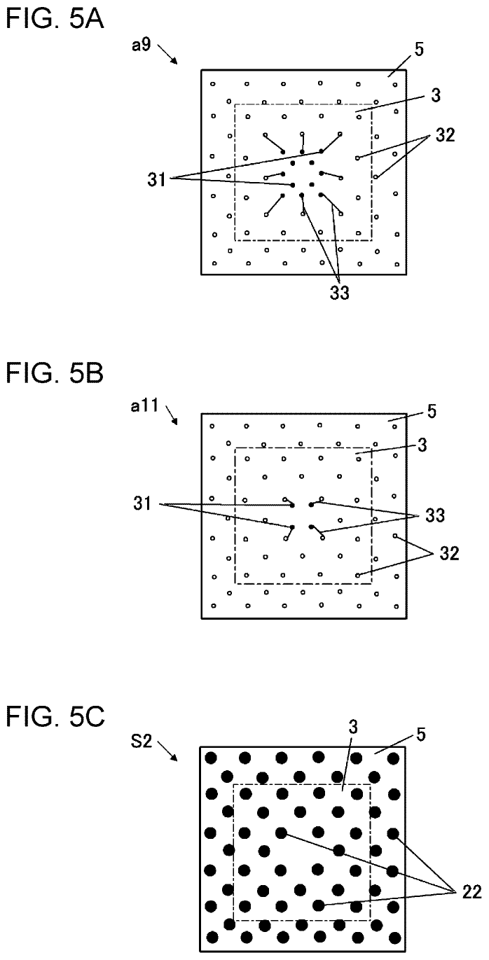

FIGS. 4A to 4D and FIGS. 5A to 5C are views of a wiring pattern of Embodiment 1. FIG. 4A illustrates the first surface, FIGS. 4B to 4D illustrate a third wiring layer, a fifth wiring layer, and a seventh wiring layer, respectively, FIGS. 5A and 5B illustrate a ninth wiring layer and an eleventh wiring layer, respectively, and FIG. 5C illustrates the second surface. In FIGS. 4A to 4D and FIGS. 5A and 5B, a black circle indicates the first via conductor 31 and a white circle indicates the second via conductor 32.

As illustrated in FIG. 4A, the multiple first electrodes 21 may be located in the center region 3. As illustrated in FIG. 5C, at least some of the multiple second electrodes 22 may be located in the outer peripheral region 5. With such a configuration, the multiple second electrodes 22 can include a larger gap therebetween and electrical coupling between the wiring board 1 and a substrate of a test device can be easier. In addition, the multiple first electrodes 21 can be disposed closely to one another in such a manner as to correspond to multiple terminals of an electronic circuit of a test target object.

As illustrated in FIG. 2, FIGS. 4B to 4D, and FIGS. 5A and 5B, each of the multiple film conductors 33 may extend from the first via conductor 31 to the second via conductor 32 in a direction from the center region 3 toward the outer peripheral region 5. With such a configuration, the multiple first electrodes can be disposed closely to one another in the center region 3 while the multiple second electrodes can include a larger gap therebetween.

As illustrated in FIG. 2, FIGS. 4B to 4D, and FIGS. 5A and 5B, the number (36 in the drawings) of second via conductors 32 located in the outer peripheral region 5a within half a thickness of the wiring board 1 from the first surface S1 may be larger than the number (0 in the drawings) of first via conductors 31 located in the outer peripheral region 5a within half the thickness.

Among the multiple second via conductors 32 located in the outer peripheral region 5, the number (36 in the drawings) of second via conductors 32 with a portion located within half the thickness (for example, the wiring layer a3, a5) from the first surface S1 may be larger than the number (0 in the drawings) of second via conductors 32 without any portion located within half the thickness (for example, the wiring layer a3, a5) from the first surface S1.

With such a configuration, many of the film conductors 33 coupled to the second electrodes 22 closer to the outer periphery of the wiring board 1 can be disposed at the wiring layers closer to the first surface S1. In addition, many of the film conductors 33 coupled to the second electrodes 22 closer to the center of the wiring board 1 among the multiple second electrodes 22 can be disposed at the wiring layers farther from the first surface S1. With such a configuration, the multiple film conductors 33 can be disposed in such a manner as to be distributed to positions closer to the first surface S1, farther from the first surface S1, in the center region 3, and in the outer peripheral region 5. Therefore, a decrease in a region secured for each film conductor 33 can be reduced. Accordingly, the film conductor 33 can have an improved degree of freedom in routing and have wider line width. Thereby, the film conductor 33 can have a lower resistance value, which can reduce a resistance value of the wiring conductor 30.

As illustrated in FIGS. 4B to 4D and FIGS. 5A and 5B, the number (36 in the drawings) of film conductors 33 located at the wiring layer a3, a5 closer to the first surface S1 than to the second surface S2 may be larger than the number (12 in the drawings) of film conductors 33 located at the wiring layer a9, all closer to the second surface S2 than to the first surface S1.

With such a configuration, the number of film conductors 33 located closer to the outer periphery of the wiring board can be larger than the number of film conductors 33 located closer to the center of the wiring board 1. In the wiring board 1, the region closer to the outer periphery has a longer distance in a circumferential direction. Thereby, with the configuration described above, a large number of film conductors 33 can be disposed in such a manner as to be distributed in a region wide in the circumferential direction. Therefore, with regard to the comparatively small number of film conductors 33 located closer to the center as well as the comparatively large number of film conductors 33 located closer to the outer periphery, the film conductors 33 can have an improved degree of freedom in routing and have wider line width. Thereby, all of the wiring conductors 30 can uniformly have reduced resistance.

As illustrated in FIGS. 4B to 4D and FIGS. 5A and 5B, the film conductor 33 located at the wiring layer a3, a5 closer to the first surface S1 than to the second surface S2 may be longer than the film conductor 33 located at the wiring layer a9, a11 closer to the second surface S2 than to the first surface S1.

With such a configuration, the film conductor 33 located closer to the outer periphery of the wiring board is longer than the film conductor 33 located closer to the center of the wiring board 1. In the wiring board 1, the region closer to the outer periphery has the longer distance in the circumferential direction. Thereby, with the configuration described above, the longer film conductors 33 can be disposed in such a manner as to be distributed in a region wide in the circumferential direction. Therefore, the longer film conductors 33 can easily have wider line width. Accordingly, the longer film conductors 33 can have further lower resistivity, and all of the wiring conductors 30 can uniformly have reduced resistance.

As illustrated in FIG. 2, the multiple film conductors 33 include two film conductors 33A and 33B adjacent to one another in the vertical direction. When such film conductors 33A and 33B are included, the ground conductor 40 may be located between the two film conductors 33A and 33B. With such a configuration, a wiring conductor 30A including the film conductor 33A and a wiring conductor 30B including the film conductor 33B can have reduced electrical interference therebetween. Note that the ground conductor 40 is located between every pair of film conductors 33 vertically adjacent to one another, and thus the adjacent wiring conductors 30 can have reduced electrical interference therebetween. However, the ground conductor 40 is not necessarily located between every pair of film conductors 33 vertically adjacent to one another. As a rate of the ground conductors 40 each located between a pair of film conductors 33 adjacent to one another increases, a larger effect of reducing electrical interference between the adjacent wiring conductors 30 is obtainable.

### Embodiment 2

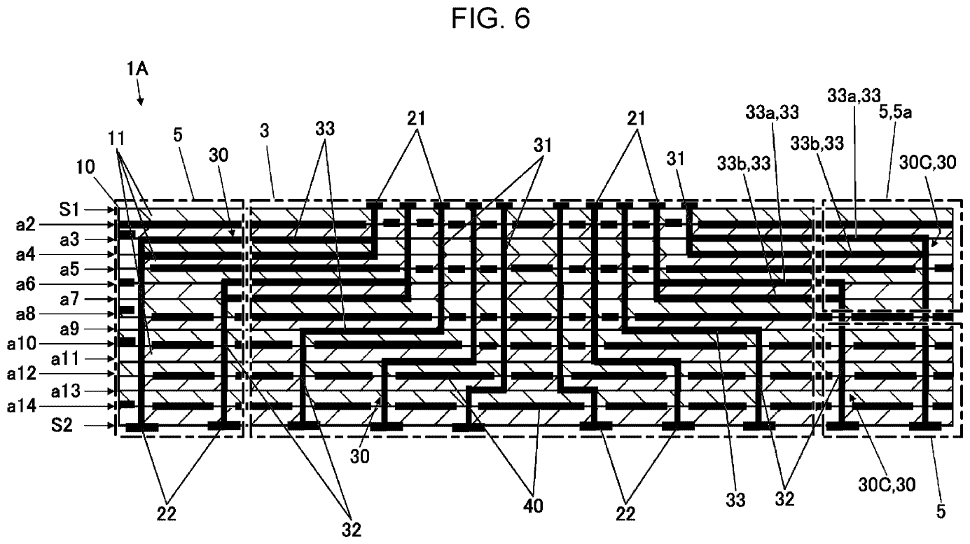

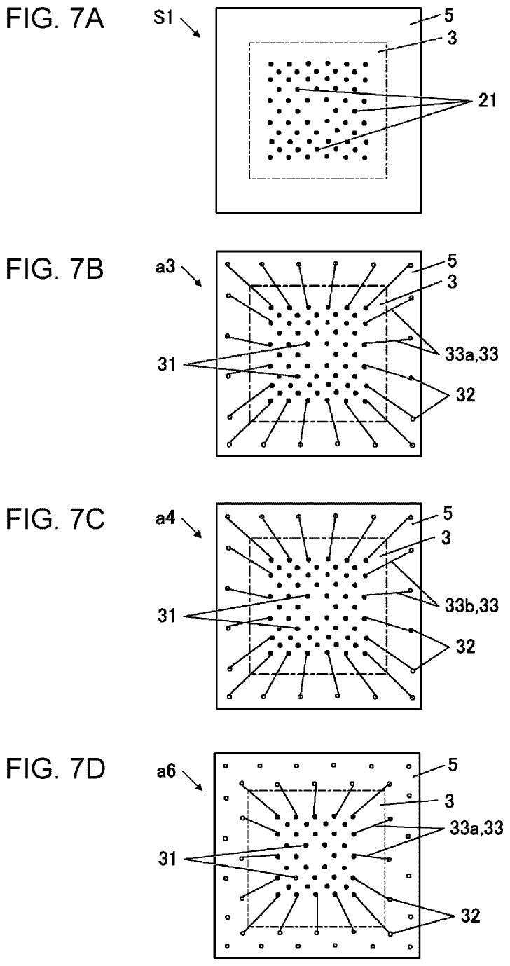

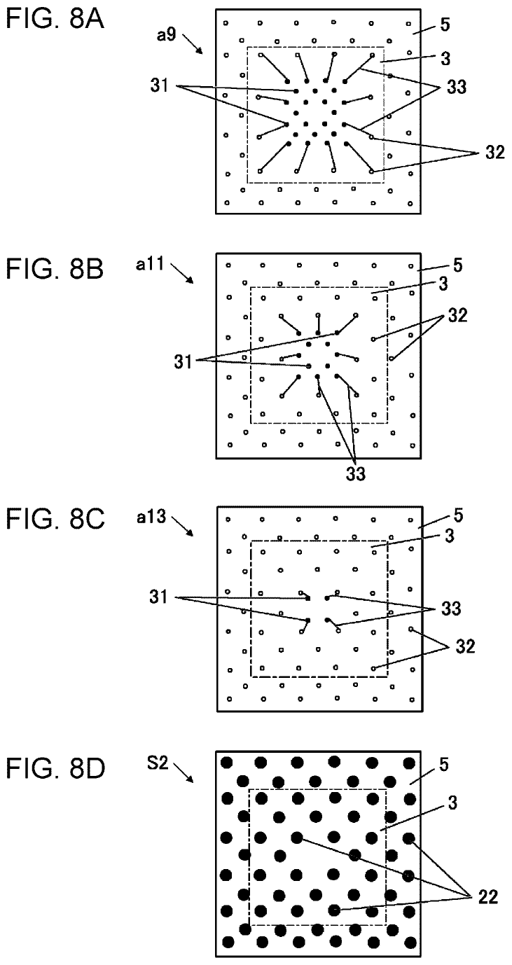

FIG. 6 is a vertical sectional view of a wiring board of Embodiment 2. FIGS. 7A to 7D and FIGS. 8A to 8D are views of a wiring pattern of wiring conductors of Embodiment 2. FIG. 7A illustrates the first surface S1, FIGS. 7B to 7D illustrate the third wiring layer a3, the fourth wiring layer a4, and the sixth wiring layer a6, respectively, FIGS. 8A to 8C illustrate the ninth wiring layer a9, the eleventh wiring layer a11, and a thirteenth wiring layer a13, respectively, and FIG. 8D illustrates the second surface S2. In FIGS. 7A to 7D and FIGS. 8A to 8C, a black circle indicates the first via conductor 31 and a white circle indicates the second via conductor 32.

A wiring board 1A of Embodiment 2 may include the same and/or similar configuration as or to the wiring board 1 of Embodiment 1, except for difference in some components. The same and/or similar components are denoted by the same reference signs to omit detailed description. The wiring board 1A of Embodiment 2 includes the same and/or similar configuration with regard to distribution of the first via conductors 31 and the second via conductors 32 (for example, greater or less in number in comparison between multiple regions) and distribution of the multiple film conductors 33 (for example, greater or less in number in comparison between multiple regions, and greater or less in length in comparison between multiple regions) described in Embodiment 1.

In the wiring board 1A of Embodiment 2, a wiring conductor 30C with the film conductor 33 located at at least within half a thickness of the wiring board 1A from the first surface S1 may include multiple film conductors 33a and 33b coupled in parallel to one another. The multiple film conductors 33a and 33b coupled in parallel to one another may be located at respective ones of two wiring layers vertically adjacent to one another (for example, the wiring layers a3 and a4 or the wiring layers a6 and a7). Note that the number of multiple film conductors coupled in parallel to one another may be n (n is an integer of 3 or more), and in such a configuration, the n film conductors may be located at respective ones of n wiring layers vertically adjacent to one another.

With such a configuration, with regard to the wiring conductor 30C including the comparatively long film conductor 33 among the multiple film conductors 33, the multiple film conductors 33a and 33b coupled in parallel to one another are adoptable. Therefore, the longer film conductor 33 can have reduced resistance. Thereby, all of the wiring conductors 30 including the wiring conductor 30C with the longer film conductor 33 and the wiring conductor 30 with the shorter film conductor 33 can uniformly have reduced resistance.

As illustrated in FIGS. 7B and 7C, the multiple film conductors 33a and 33b coupled in parallel to one another may be located at the respective ones of the multiple successive wiring layers a3 and a4 (that is, the multiple wiring layers a3 and a4 vertically adjacent to one another) and include the same pattern. Including the same pattern allows the multiple film conductors 33a and 33b coupled in parallel to one another to be fabricated by using the same pattern fabrication configuration (for example, pattern printing configuration). Since the same pattern fabrication configuration is usable, the film conductors 33a and 33b can have less variation in line width. This is because, when the film conductors are fabricated by using different pattern fabrication configurations, an installation error of a component (for example, a pattern mask) in the pattern fabrication configurations changes, which brings a factor for variation in line width. Therefore, including the same pattern as described above reduces variation in line width and can reduce resistance variation of the film conductors 33a and 33b and the wiring conductor 30C (see FIG. 6).

### Embodiment 3

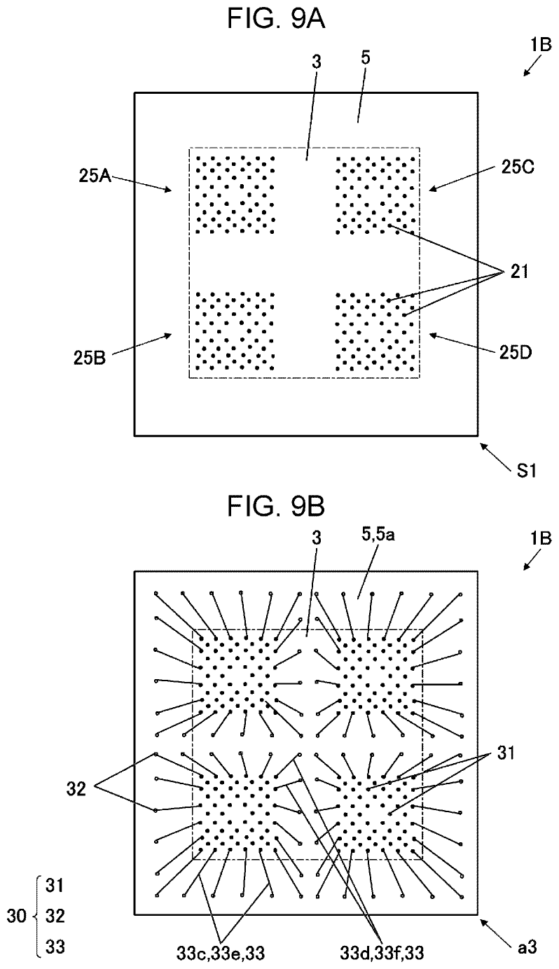

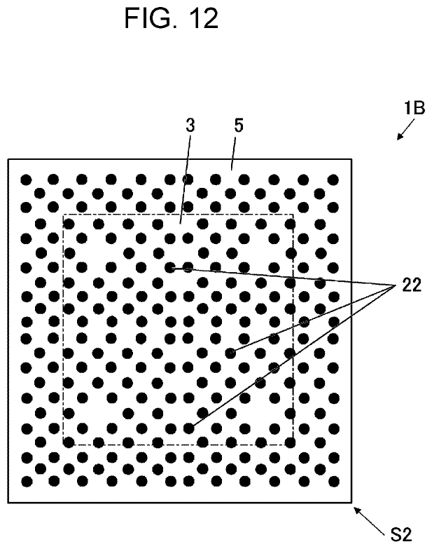

FIGS. 9A to 12 are views of a wiring pattern of a wiring board of Embodiment 3. FIG. 9A illustrates the first surface S1, FIGS. 9B, 10A, 10B, 11A, and 11B illustrate the third wiring layer a3, the fifth wiring layer a5, the seventh wiring layer a7, the ninth wiring layer a9, and the eleventh wiring layer a11, respectively, and FIG. 12 illustrates the second surface S2. In FIGS. 9A to 11B, a black circle indicates the first via conductor 31 and a white circle indicates the second via conductor 32.

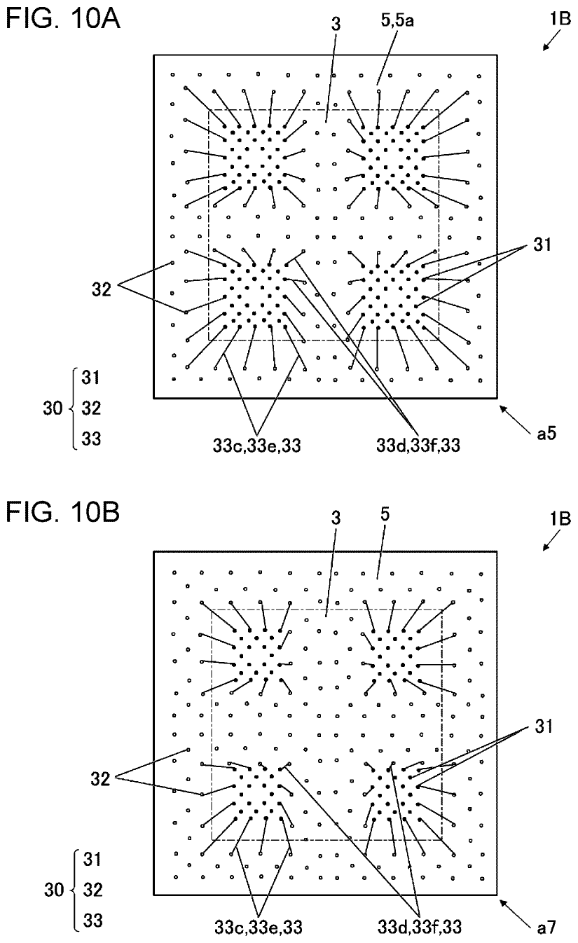

A wiring board 1B of Embodiment 3 may include the same and/or similar configuration as or to Embodiment 1 or Embodiment 2, except for difference in a pattern of the first electrodes 21, the second electrodes 22, the first via conductors 31, the second via conductors 32, and the film conductors 33. That is, also in Embodiment 3, the same as and/or similarly to Embodiments 1 and 2, the number (88 in the drawings) of second via conductors 32 located in the outer peripheral region 5a within half a thickness of the wiring board 1B from the first surface S1 (see FIGS. 9B and 10A) may be larger than the number (0 in the drawings) of first via conductors 31 located in the outer peripheral region 5a within half the thickness (see FIGS. 9B and 10A).

Among the multiple second via conductors 32 located in the outer peripheral region 5, the number (88 in the drawings) of second via conductors 32 with a portion located within half the thickness (that is, the wiring layer a2 to a6) from the first surface S1 may be larger than the number (28 in the drawings) of second via conductors 32 without any portion located within half the thickness (that is, the wiring layer a2 to a6) from the first surface S1.

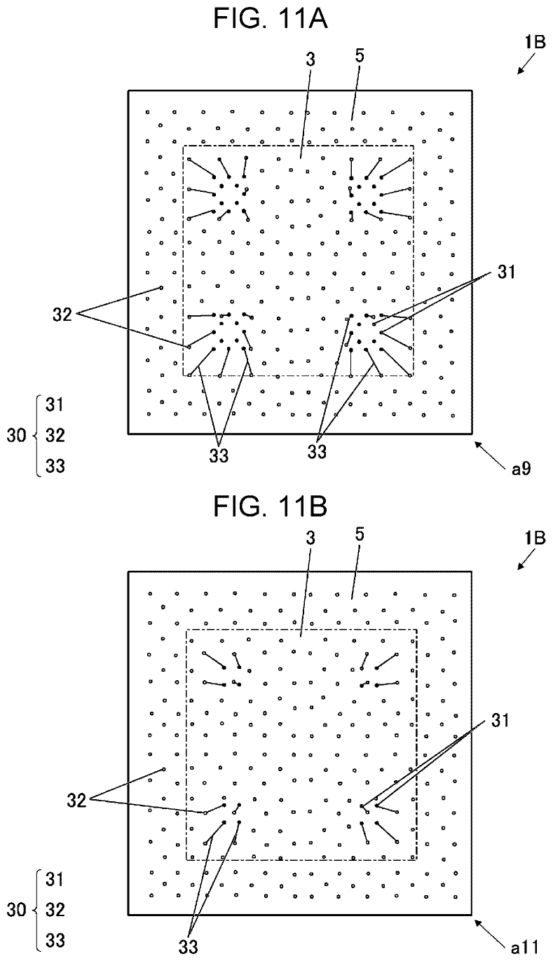

The film conductor 33 located at the wiring layer a3, a5 closer to the first surface S1 than to the second surface S2 (see FIGS. 9B and 10A) may be longer than the film conductor 33 located at the wiring layer a9, a11 closer to the second surface S2 than to the first surface S1 (see FIGS. 11A and 11B).

Also in Embodiment 3, the same as and/or similarly to Embodiments 1 and 2, the multiple film conductors 33 include two film conductors 33 adjacent to one another in the vertical direction, and the ground conductor 40 may be located between the two film conductors 33. The vertical direction means the direction orthogonal to the first surface S1.

With the above-described configuration the same as and/or similarly to the Embodiment 1, an effect the same as and/or similar to that in Embodiment 1 is achievable. In Embodiment 3, the same and/or similar components as or to those in Embodiment 1 are denoted by the same reference signs to omit detailed description.

The wiring board 1B of Embodiment 3 is adoptable to a probe card whose test target object is multiple (for example, four) electronic circuits. That is, the first surface S1 of the wiring board 1B includes multiple electrode sets 25A to 25D. Each of the multiple electrode sets 25A to 25D includes the multiple first electrodes 21 and is electrically couplable to one electronic circuit via the multiple first electrodes 21.

Relative arrangement of the multiple first electrodes 21 included in one electrode set 25A may be the same as relative arrangement of the multiple first electrodes 21 included in another electrode set 25B. The same and/or similar holds for other electrode sets 25C and 25D. “The same relative arrangement” means that the multiple first electrodes 21 included in the one electrode set 25A can overlap the multiple first electrodes 21 included in the another electrode set 25B by virtual translation or translation and rotation of the entirety of the multiple first electrodes 21 included in the one electrode set 25A without changing relative arrangement relationship of the multiple first electrodes 21 included in the one electrode set 25A.

The multiple electrode sets 25A to 25D may be disposed with a second gap interposed therebetween. The second gap is larger than (for example, five times or more) a first gap that is a gap between the multiple first electrodes 21. The first gap means an average value of gaps between adjacent first electrodes 21 among the multiple first electrodes 21 included in the one electrode set 25A.

With the configuration of the multiple electrode sets 25A to 25D described above, the multiple electrode sets 25A to 25D correspond to the respective ones of the multiple electronic circuits in a one-to-one manner, and the multiple wiring conductors 30 of the wiring board 1B are electrically couplable to the multiple electronic circuits. Therefore, use of the probe card to which the wiring board 1B is adopted allows testing of the multiple electronic circuits to be performed parallelly.

As illustrated in FIGS. 9A to 11B, the multiple film conductors 33 of Embodiment 3 include a film conductor 33c and a film conductor 33d. The film conductor 33c extends from the first via conductor 31 to the second via conductor 32 in a direction from the center region 3 toward the outer peripheral region 5. The film conductor 33d extends within the center region 3 in a direction away from the outer peripheral region 5. With such a configuration, in addition to the effect of Embodiment 1 being achievable, including the film conductor 33d allows a region between the multiple electrode sets 25A to 25D to also include the film conductors 33 disposed in a distributed manner. Accordingly, the multiple film conductors 33 can have an improved degree of freedom in routing and have wider line width. Thereby, the film conductor 33 can have a lower resistance value, which reduces a resistance value of the wiring conductor 30.

As illustrated in FIG. 9A to 12, the multiple wiring layers a2 to a12 of Embodiment 3 include the wiring layers a3, a5, and a7 including a film conductor 33e and a film conductor 33f. The film conductor 33e extends from the center region 3 to the outer peripheral region 5. The film conductor 33f extends within the center region 3. In the wiring layers a3, a5, and a7, the film conductor 33e extending from the center region 3 to the outer peripheral region 5 may be longer than the film conductor 33f extending within the center region 3. When the multiple electrode sets 25A to 25D are provided, the film conductor 33f of the one electrode set 25A may extend toward the film conductor 33f of the adjacent electrode set 25B. However, with the above-mentioned film conductors 33f having short length, the wiring conductor 30 of the one electrode set 25A and the wiring conductor 30 of the another electrode set 25B can be less likely to be close to one another in a long range. Accordingly, the multiple electrode sets 25A to 25D can have less electrical interference therebetween.

Note that, also in Embodiment 3, the configuration of Embodiment 2 in which the multiple film conductors 33 are coupled in parallel to one another is adoptable.

### <Method for Manufacturing Wiring Board>

One example of a method for manufacturing the wiring boards 1, 1A, and 1B of Embodiments 1 to 3 is described. For example, as a material for the insulating layer 11, for example, a ceramic sintered body, such as an aluminum oxide-based sintered body, an aluminum nitride-based sintered body, a silicon carbide-based sintered body, a mullite-based sintered body, or ceramics, is adoptable. When an aluminum oxide-based sintered body is adopted as the material for the insulating layer 11, the insulating substrate 10 is manufacturable as follows. First, raw material powder is mixed and kneaded together with an organic solvent and binder to make slurry. This slurry is formed into a sheet-like shape by a formation method, such as a doctor blade method or a lip coater method, to fabricate a ceramic green sheet (hereinafter, also referred to as a green sheet) that becomes the insulating layer 11. A main component of the raw material powder is aluminum oxide powder and powder, such as silicon oxide, that is a sintering aid component. Next, multiple green sheets are layered to fabricate a stacking body. Then, the stacking body is fired at a temperature of approximately 1300° C. to 1600° C., and thus the insulating substrate 10 can be manufactured.

The first electrode 21, the second electrode 22, the wiring conductor 30, and the ground conductor 40 include, as a conductor component, a metal material, such as tungsten, molybdenum, manganese, or copper, or an alloy material containing these metal materials. When the first electrode 21, the second electrode 22, the film conductor 33, and the ground conductor 40 are, for example, metallization layers including tungsten, the first electrode 21, the second electrode 22, the film conductor 33, and the ground conductor 40 can be formed in a method in which metal paste made through mixing of tungsten powder with an organic solvent and organic binder is printed in a method, such as a screen printing method, at a predetermined position of the green sheet that becomes the insulating layer 11 and sintered together with the green sheet. The first via conductor 31 and the second via conductor 32 can each be formed by providing of a through-hole to a predetermined position of the green sheet prior to the above-described printing of the metal paste, and filling of metal paste the same as and/or similar to the metal paste described above into the through-hole. On a surface of an exposed conductor layer, such as the first electrode 21 and the second electrode 22, a nickel film with a thickness of 1 to 10 m and a gold film with a thickness of 0.1 to 3 m are formed in order, thus being capable of protecting the surface as well as improving bondability of brazing material, solder, and/or the like. Each of the nickel film and the gold film can be formed by a plating film obtained by electroplating or a thin film.

### (Probe Card)

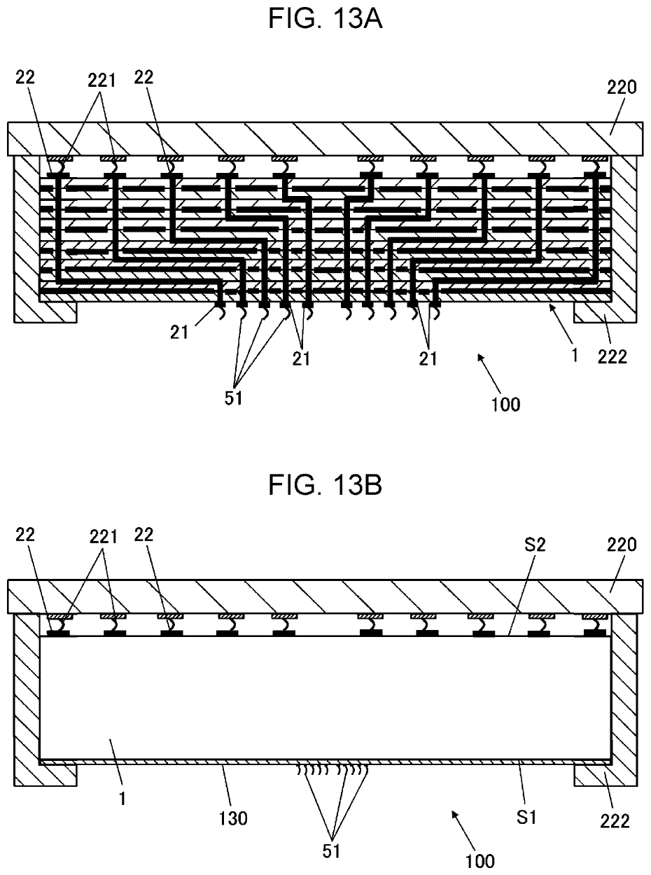

FIG. 13A is a view of a probe card according to an embodiment of the present disclosure. FIG. 13B is a view of a probe card according to a variation.

According to Embodiment 1 of the present disclosure, a probe card 100 includes the wiring board 1 and multiple probe pins 51 bonded to the respective ones of the multiple first electrodes 21. The probe pins 51 may be bonded to the respective ones of the first electrodes 21 with a bonding material, such as solder, interposed therebetween. The wiring board 1 may be substituted by the wiring board 1A or 1B.

The probe card 100 is supported by a frame body 222. The probe card 100 is electrically coupled to a circuit board 220 coupled to a test device, which is not illustrated, with multiple contact conductors 221 interposed therebetween. The multiple contact conductors 221 are coupled to the respective ones of the multiple second electrodes 22. The multiple contact conductors 221 may include respective center portions supported by an insulation board or an insulation sheet not illustrated, thereby being integrated together. Such a configuration may be referred to as an interposer.

In the probe card 100 with such a configuration, the probe pin 51 of the probe card 100 is coupled to an electrode of an electronic circuit (for example, an electronic circuit provided to a silicon wafer) of a test target object. A test device, which is not illustrated, coupled to the circuit board 220 can communicate one or both of a signal and power supply voltage with the electronic circuit of the test target object via the circuit board 220, the multiple contact conductors 221, the wiring board 1, and the probe pins 51. Therefore, the test device can test the test target object.

Note that the multiple probe pins 51 are not necessarily directly bonded to the first electrodes 21. As illustrated in FIG. 13B, the multiple probe pins 51 may electrically be coupled to the respective ones of the multiple first electrodes 21 with a resin substrate 130 including a thin-film wiring layer interposed therebetween. The resin substrate 130 may include multiple resin layers. For example, polyimide is adoptable as a material for the resin substrate 130. The resin substrate 130 may include multiple electrodes on one surface facing the wiring board 1 and may include, on an opposite surface, multiple electrodes to which the respective ones of the multiple probe pins 51 are bonded. The resin substrate 130 may include thin-film wiring electrically coupling the electrode on the one surface and the electrode on the opposite surface. Use of the resin substrate 130 allows the wiring conductor and the electrode of the resin substrate 130 to be miniaturized and facilitates densification of the probe pins 51.

Each embodiment of the present disclosure has been described above. However, the probe card and the wiring board of the present disclosure are not limited to those of the embodiments described above, and can suitably be changed without departing from the spirit of the invention. For example, the embodiments describe the example in which all the electrodes located on the first surface of the wiring board are first electrodes. However, an electrode other than the first electrode may be located on the first surface of the wiring board. Such an electrode other than the first electrode may be located in the outer peripheral region. Furthermore, the embodiments describe the example in which all the conductors (more specifically, the conductors other than the ground conductors) located inside the wiring board are the wiring conductors each including the first via conductor, the film conductor, and the second via conductor coupled to one another. However, the wiring conductors may include a wiring conductor including one via conductor, and/or may include some wiring conductors each with multiple steps continuing in a step-like manner. The components of the multiple embodiments described above may partially be interchanged with one another, and/or one or some of the components of one embodiment may be added to another embodiment.

Below, an embodiment of the present disclosure is described. In an embodiment, (1) a wiring board includes: an insulating substrate including a first surface, a second surface located opposite to the first surface, and multiple wiring layers; multiple first electrodes located on the first surface; multiple second electrodes located on the second surface; and multiple wiring conductors extending between respective ones of the multiple first electrodes and corresponding ones of the multiple second electrodes, wherein the multiple wiring conductors include: respective ones of film conductors each located at any of the multiple wiring layers; respective ones of first via conductors extending between the respective ones of the film conductors and corresponding ones of the multiple first electrodes; and respective ones of second via conductors extending between the respective ones of the film conductors and corresponding ones of the multiple second electrodes, the insulating substrate includes a center region and an outer peripheral region, wherein when a line segment connecting a center and an outer periphery of the insulating substrate in transparent plan view is drawn, the center region covers a range of two-thirds of the line segment closer to the center in any direction, and the outer peripheral region covers a range of one-thirds of the line segment closer to the outer periphery in any direction, the multiple first electrodes are located in the center region, at least some of the multiple second electrodes are located in the outer peripheral region, and among the second via conductors located in the outer peripheral region, a number of the second via conductors with a portion located within half a thickness of the insulating substrate from the first surface is larger than a number of the second via conductors not located within half the thickness of the insulating substrate from the first surface.
(2) The wiring board of (1), wherein a number of the film conductors each located at a wiring layer closer to the first surface than to the second surface is larger than a number of the film conductors each located at a wiring layer closer to the second surface than to the first surface.
(3) The wiring board of (1) or (2), wherein the film conductors each located at a wiring layer closer to the first surface than to the second surface is longer than the film conductors each located at a wiring layer closer to the second surface than to the first surface.
(4) The wiring board of any one of (1) to (3), wherein among the multiple wiring conductors, a wiring conductor with a film conductor included in the film conductors and located at at least within half the thickness of the insulating substrate from the first surface includes the film conductor including multiple film conductors coupled in parallel to one another.
(5) The wiring board of (4), wherein the multiple film conductors coupled in parallel to one another are located at respective ones of multiple wiring layers vertically adjacent to one another and include a same pattern as one another.
(6) The wiring board of any one of (1) to (5), wherein the multiple wiring conductors include a first wiring conductor and a second wiring conductor, the film conductors include a film conductor of the first wiring conductor and a film conductor of the second wiring conductor vertically adjacent to one another in a vertical cross section, and a ground conductor is located between the film conductor of the first wiring conductor and the film conductor of the second wiring conductor.
(7) The wiring board of any one of (1) to (6), wherein the multiple wiring layers include a wiring layer with a film conductor included in the film conductors and extending from the center region to the outer peripheral region and a film conductor included in the film conductors and extending within the center region, and in the wiring layer, the film conductor extending from the center region to the outer peripheral region is longer than the film conductor extending within the center region.

In an embodiment, (8) a probe card includes: the wiring board of any one of (1) to (7); and multiple probe pins.

### INDUSTRIAL APPLICABILITY

The present invention is applicable to a circuit board and a probe card.

### REFERENCE SIGNS

1, 1A, 1B wiring board
3 center region
5 outer peripheral region
5a outer peripheral region within half thickness from first surface
10 insulating substrate
S1 first surface
a2-a14 wiring layer
S2 second surface
21 first electrode
22 second electrode
30, 30A-30C wiring conductor
31 first via conductor
32 second via conductor
33, 33a-33f film conductor
40 ground conductor
51 probe pin
100 probe card
130 resin substrate

1. A wiring board comprising:
an insulating substrate comprising a first surface, a second surface located opposite to the first surface, and multiple wiring layers;
multiple first electrodes located on the first surface;
multiple second electrodes located on the second surface; and
multiple wiring conductors extending between respective ones of the multiple first electrodes and corresponding ones of the multiple second electrodes, wherein
the multiple wiring conductors comprise:
respective ones of film conductors each located at any of the multiple wiring layers;
respective ones of first via conductors extending between the respective ones of the film conductors and corresponding ones of the multiple first electrodes; and
respective ones of second via conductors extending between the respective ones of the film conductors and corresponding ones of the multiple second electrodes,
the insulating substrate comprises a center region and an outer peripheral region, wherein when a line segment connecting a center and an outer periphery of the insulating substrate in transparent plan view is drawn, the center region covers a range of two-thirds of the line segment closer to the center in any direction, and the outer peripheral region covers a range of one-thirds of the line segment closer to the outer periphery in any direction,
the multiple first electrodes are located in the center region,
at least some of the multiple second electrodes are located in the outer peripheral region, and
among the second via conductors located in the outer peripheral region, a number of the second via conductors with a portion located within half a thickness of the insulating substrate from the first surface is larger than a number of the second via conductors not located within half the thickness of the insulating substrate from the first surface.

2. The wiring board according to claim 1, wherein a number of the film conductors each located at a wiring layer closer to the first surface than to the second surface is larger than a number of the film conductors each located at a wiring layer closer to the second surface than to the first surface.

3. The wiring board according to claim 1, wherein the film conductors each located at a wiring layer closer to the first surface than to the second surface is longer than the film conductors each located at a wiring layer closer to the second surface than to the first surface.

4. The wiring board according to any one of claim 1, wherein among the multiple wiring conductors, a wiring conductor with a film conductor comprised in the film conductors and located at at least within half the thickness of the insulating substrate from the first surface comprises the film conductor comprising multiple film conductors coupled in parallel to one another.

5. The wiring board according to claim 4, wherein the multiple film conductors coupled in parallel to one another are located at respective ones of multiple wiring layers vertically adjacent to one another and comprise a same pattern as one another.

6. The wiring board according to any one of claim 1, wherein the multiple wiring conductors comprise a first wiring conductor and a second wiring conductor,
the film conductors comprise a film conductor of the first wiring conductor and a film conductor of the second wiring conductor vertically adjacent to one another in a vertical cross section, and
a ground conductor is located between the film conductor of the first wiring conductor and the film conductor of the second wiring conductor.

7. The wiring board according to any one of claim 1, wherein the multiple wiring layers comprise a wiring layer with a film conductor comprised in the film conductors and extending from the center region to the outer peripheral region and a film conductor comprised in the film conductors and extending within the center region, and
in the wiring layer, the film conductor extending from the center region to the outer peripheral region is longer than the film conductor extending within the center region.

8. A probe card comprising:
the wiring board according to any one of claim 1; and
multiple probe pins.
